(19) United States
(12) Patent Application Publication
(10) Pub. No.: US 2010/0033927 A1
(43) Pub. Date: Feb. 11, 2010

(54) Eject mechanism and electrical apparatus comprising the same

(75) Inventor: Keisuke Nakamura, Tokyo (JP)

Correspondence Address: COLLARD & ROE, P.C., 1077 NORTHERN BOULEVARD, ROSLYN, NY, 11576, US

(73) Assignee: Japan Aviation Electronics Industry, Limited

(21) Appl. No.: 12/456,887

(22) Filed: Jun. 24, 2009

(30) Foreign Application Priority Data
Aug. 5, 2008 (JP) 2008-202028

(51) Int. Cl. H05K 7/00

(52) U.S. Cl. 361/679.58

(57) ABSTRACT

An eject mechanism comprises an eject member, a lock member and a lock release member. The eject member is configured to, when an object is positioned at a predetermined position, eject the object from the predetermined position along an eject direction. The lock member is configured to lock the object on the predetermined position against the eject member. The lock release member is configured to, when the lock release member is moved in the eject direction, release the lock of the object by the lock member. The eject mechanism ejects the object when the lock release member is moved in the eject direction.

### CROSS REFERENCE TO RELATED APPLICATION

An applicant claims priority under 35 U.S.C. §119 of Japanese Patent Application No. 2008-202028 filed Aug. 5, 2008.

### BACKGROUND OF THE INVENTION

This invention relates to an eject mechanism used in an electrical apparatus which can accommodate an object; the electrical apparatus is for example a laptop PC or a mobile phone; the object is for example a card or a drive bay. The eject mechanism is configured to eject the object from the electrical apparatus.

For example, an eject mechanism of the above-mentioned type is disclosed in JP-A 2006-38170, which is incorporated herein by reference in its entirety. The disclosed eject mechanism carries out ejection of an object when the object is pushed out along the eject direction.

However, the disclosed eject mechanism has a problem that the object may be ejected when the object is pushed unexpectedly.

### SUMMARY OF THE INVENTION

It is an object of the present invention to provide an eject mechanism that has a structure for preventing the object from being ejected unexpectedly.

An aspect of the present invention provides an eject mechanism. The eject mechanism comprises an eject member, a lock member and a lock release member. The eject member is configured to, when an object is located on a predetermined position, eject the object from the predetermined position along an eject direction. The lock member is configured to lock the object on the predetermined position against the eject member. The lock release member is configured to, when the lock release member is moved in the eject direction, release the lock of the object by the lock member.

An appreciation of the objectives of the present invention and a more complete understanding of its structure may be had by studying the following description of the preferred embodiment and by referring to the accompanying drawings.

### BRIEF DESCRIPTION OF THE DRAWINGS

FIG. 1 is a perspective view showing a drive bay and an eject mechanism according to a first embodiment of the present invention.

FIG. 2 is a perspective view showing the eject mechanism of FIG. 1. A cover is not shown. A lever is positioned at a pull position. The drive bay is positioned at a predetermined position.

FIG. 3 is a perspective view showing the eject mechanism of FIG. 1. The cover is not shown. A lock release member is moved in an eject direction. The drive bay is in an eject state.

FIG. 4 is a perspective view showing a bottom part of the eject mechanism of FIG. 1.

FIG. 5 is a perspective view showing a base member included in the eject mechanism of FIG. 1.

FIG. 6 is a perspective view showing a bottom part of the base member of FIG. 5.

FIG. 7 is a perspective view showing an eject member included in the eject mechanism of FIG. 1.

FIG. 8 is a perspective view showing a bottom part of the eject member of FIG. 7.

FIG. 9 is a perspective view showing a lock member included in the eject mechanism of FIG. 1.

FIG. 10 is a perspective view showing a bottom part of the lock member of FIG. 9.

FIG. 11 is a perspective view showing the lock member of FIG. 9 and a detector.

FIG. 12 is a perspective view showing a lock release member included in the eject mechanism of FIG. 1.

FIG. 13 is a perspective view showing a bottom part of the lock release member of FIG. 12.

FIG. 14 is a perspective view showing a lever included in the eject mechanism of FIG. 1.

FIG. 15 is a perspective view showing a cover included in the eject mechanism of FIG. 1.

FIG. 16 is a perspective view showing an eject member included in an eject mechanism according to a second embodiment of the present invention.

FIG. 17 is a perspective view showing a lock member included in the eject mechanism of the second embodiment.

FIG. 18 shows the eject member of FIG. 16 and the lock member of FIG. 17, wherein the eject member is locked by the lock member.

FIG. 19 shows the eject member of FIG. 16 and the lock member of FIG. 17, wherein the eject member is not locked by the lock member.

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### Description of the Preferred Embodiments

### First Embodiment

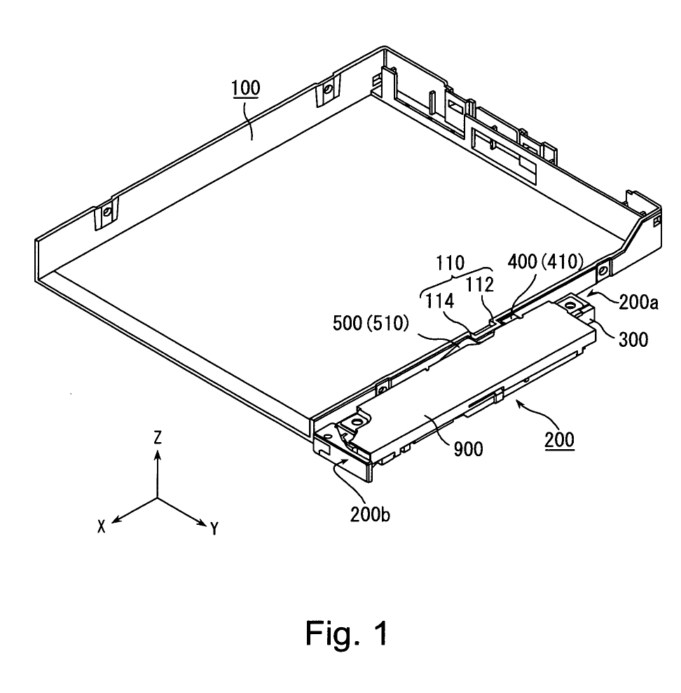

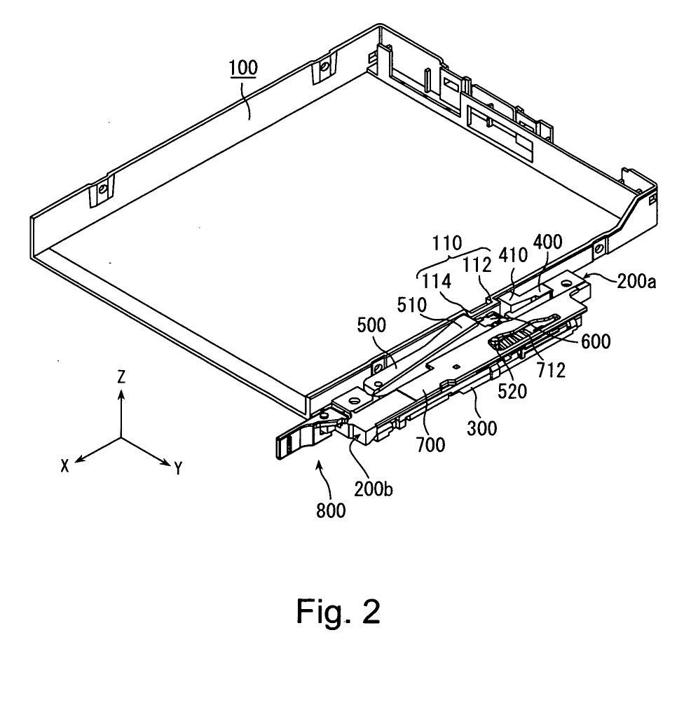

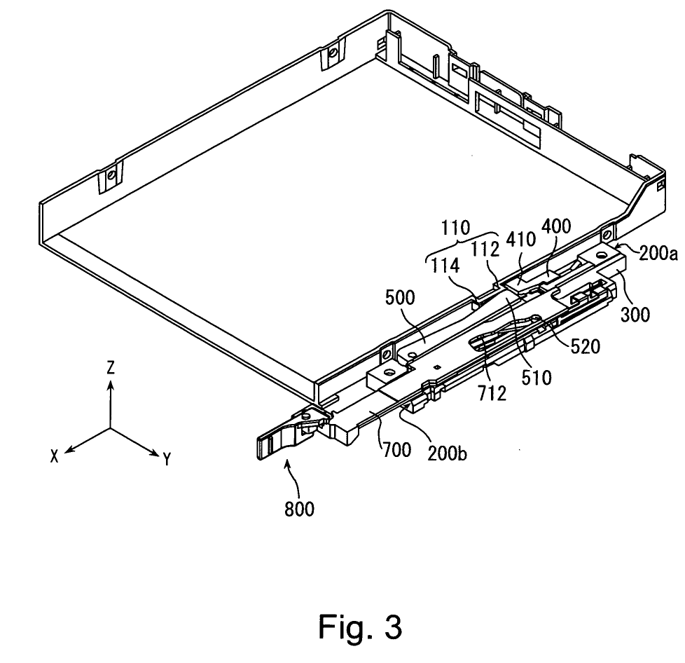

With reference to FIGS. 1 and 2, an electrical apparatus (not shown) has a drive bay (an object) 100 and an eject mechanism 200. The drive bay 100 is positioned at a predetermined position. With reference to FIG. 3, the eject mechanism 200 according to a first embodiment of the present invention is configured to eject the drive bay 100 from the electrical apparatus (not shown) along an eject direction which is a direction from a front end 200a toward a back end 200b of the eject mechanism 200. In other words, the eject mechanism 200 is configured to move the drive bay 100 from the predetermined position along the eject direction so that the drive bay 100 is in an eject state. In the present embodiment, an opposite direction to the eject direction is referred to as an insert direction. In other words, the insert direction is a direction from the back end 200b toward the front end 200a.

As shown in FIGS. 1 to 3, the drive bay 100 comprises a projection 110 projecting in a Y-direction. The projection 110 comprises a pressed portion 112 and a received portion 114.

With reference to FIGS. 1 to 3, the eject mechanism 200 comprises a base member 300, an eject member 400, a lock member 500, a detector 600, a lock release member 700, a lever 800 and a cover 900.

With reference to FIGS. 1 and 4 to 6, the base member 300 supports the eject member 400, the lock member 500, the detector 600 and the lock release member 700. The base member 300 has a specific structure to support them.

In detail, to support the eject member 400, the base member 300 comprises a guide groove 310, a guide recess 312 and a projection 316. The base member 300 has a top side and a bottom side. The guide groove 310 is formed on the bottom side and is positioned in the vicinity of a center of the base member 300 in the X-direction. The base member 300 has a front end 300a and a back end 300b in the X-direction. The guide recess 312 is formed on the top side and is positioned closer to the front end 300a than the guide groove 310. The projection 316 is formed on the top side and is positioned closer to the back end 300b of the base member 300 than the guide groove 310. The projection 316 projects upwardly in a Z-direction.

To support the lock member 500, the base member 300 comprises a pivot 320, a beam 322 and a projection 326. The pivot 320 is formed on the top side of the base member 300 and is positioned closer to the back end 300b of the base member 300 than the guide groove 310. The pivot 320 projects upwardly in the Z-direction. The base member 300 further has a cavity 324. The beam 322 is formed on the top side of the base member 300 and extends in the X-direction so that the cavity 324 is positioned under the beam 322 in the Z-direction. The projection 326 is formed on the bottom side of the base member 300 and is positioned closer to the front end 300a than the beam 322 in the X-direction. The projection 326 projects downwardly in the Z-direction.

To support the lock release member 700, the base member 300 comprises a guide portion 331, an opening 332 and a projection 334. The guide portion 331 is formed on the top side of the base member 300. The guide portion 331 extends from the back end 300b toward the front end 300a of the base member 300. The opening 332 has a narrow shape and extends in the X-direction. The opening 332 is closer to the front end 300a than the guide portion 331 in the X-direction. The projection 334 is formed on the bottom side of the base member 300 and is closer to the front end 300a than the opening 332. The projection 334 projects downwardly in the Z-direction.

To support the detector 600 partially, the base member 300 comprises two hold portions 351 and 352, an accommodation portion 353 and two press fitted portions 354 and 355. The hold portions 351 and 352 and the accommodation portion 353 are formed on the top side of the base member 300. The press fitted portions 354 and 355 are formed in the base member 300 and extend in the Z-direction.

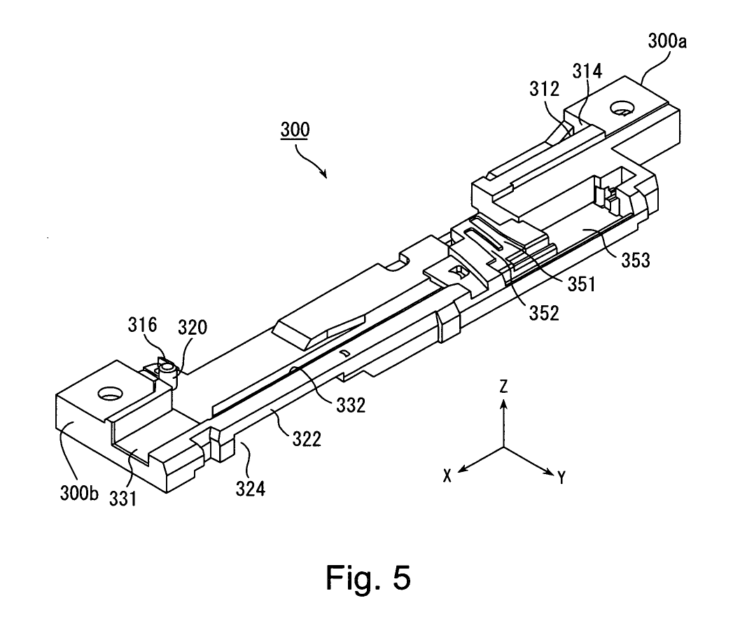

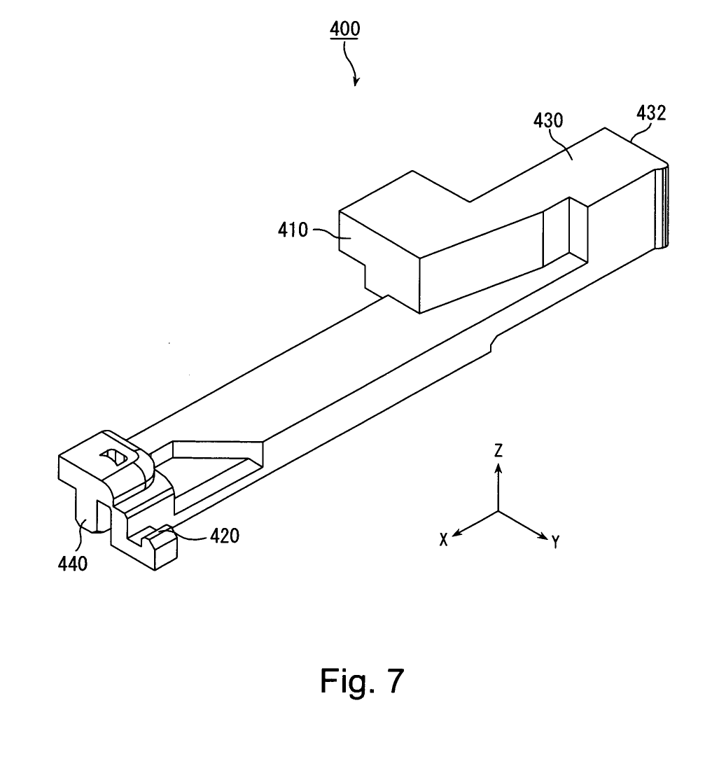

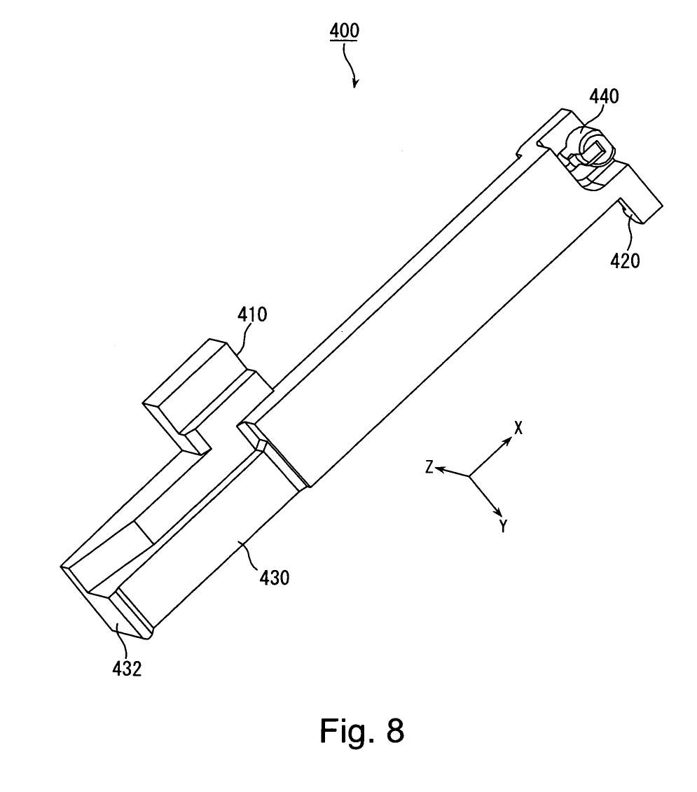

With reference to FIGS. 7 and 8, the eject member 400 used to eject the drive bay 100 in the eject direction. In other words, the eject member 400 is used to move the drive bay 100 from the predetermined position in the eject direction when the drive bay 100 is positioned at the predetermined position. The eject member 400 comprises a press portion 410, guided portions 420 and 430 and a projection 440. The press portion 410 is configured to press the pressed portion 112 of the drive bay 100. The guided portion 420 is movable along the guide groove 310. The guided portion 430 is movable along the guide recess 312. The projection 440 projects downwardly in the Z-direction. The eject member 400 is supported by the base member 300 so that the eject member 400 is movable in the X-direction. In this embodiment, with reference to FIGS. 5, 7 and 8, the eject member 400 has a contact portion 432. The base member 300 has a contact surface 314. The contact portion 432 of the eject member 400 is brought into contact with the contact surface 314 of the base member 300 when the drive bay 100 is positioned at the predetermined position (See FIG. 2).

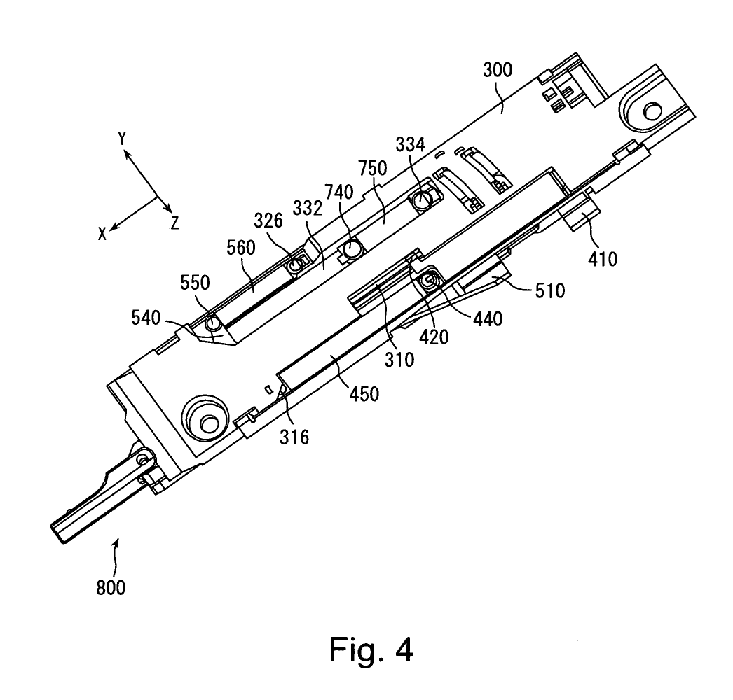

With reference to FIG. 4, the eject mechanism 200 is provided with a coil spring 450 which connects the projection 316 of the base member 300 and the projection 440 of the eject member 400. The press portion 410 presses the pressed portion 112 of the drive bay 100 in the eject direction in accordance with the bias by the coil spring 450. Therefore, the coil spring 450 serves as an eject bias member which biases the eject member 400 in the eject direction.

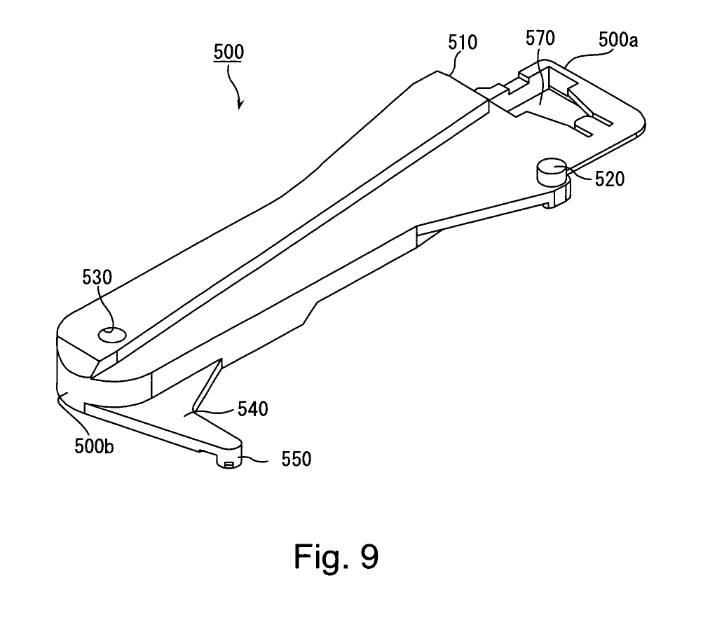

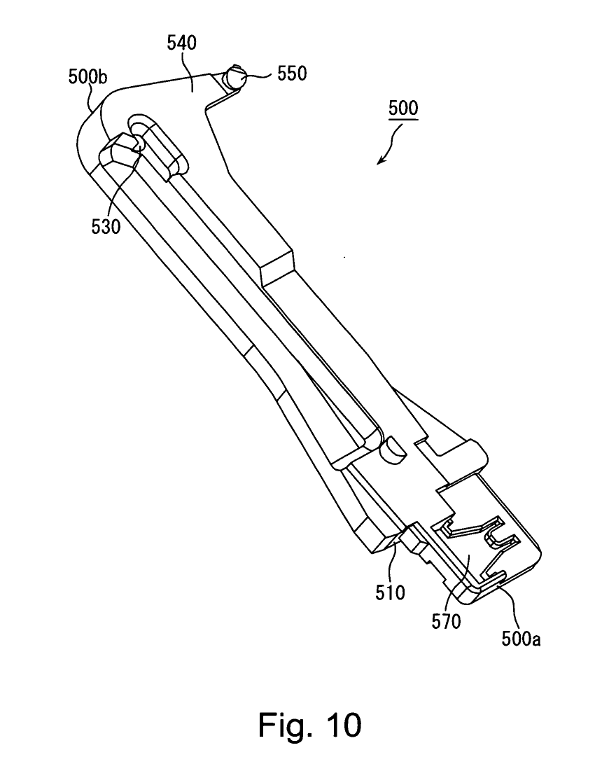

With reference to FIGS. 9 and 10, the lock member 500 is configured to lock the drive bay 100 on the predetermined position against the eject member 400. The lock member 500 comprises a receive portion 510, a cam follower 520, a projection 550, a pivot hole 530 and an arm portion 540. The receive portion 510 is configured to receive the received portion 114 of the drive bay 100. The lock member 500 has a front end 500a and a back end 500b in the X-direction and has a top side and a bottom side. The cam follower 520 is formed on the top side of the lock member 500 and is positioned closer to the front end 500a than to the back end 500b of the lock member 500. The pivot hole 530 is positioned in the vicinity of the back end 500b of the lock member 500. The pivot 320 of the base member 300 is inserted into the pivot hole 530. The arm portion 540 extends in the Y-direction. The arm portion 540 has a front end portion in the Y-direction. The projection 550 is formed at the front end portion of the arm portion 540 and projects downwardly. With reference to FIGS. 2, 5, 9 and 10, the lock member 500 of the embodiment is supported by the base member 300 so that the lock member 500 is pivotable on the pivot 320 of the base member 300. With this structure, the lock member 500 is movable between a lock position and an unlock position. As shown in FIG. 2, the received portion 114 is received by the receive portion 510 of the lock member 500 when the lock member 500 is positioned at the lock position. As shown in FIG. 3, the received portion 114 is not received by the receive portion 510 of the lock member when the lock member 500 is positioned at the unlock position.

With reference to FIG. 4, the eject mechanism 200 is provided with a coil spring 560 which connects the projection 550 of the lock member 500 and the projection 326 of the base member 300. The lock member 500 locks the drive bay 100 on the predetermined position when the lock member 500 is positioned at the lock position. Therefore, the coil spring 560 serves as a lock bias member which biases the lock member 500 so that the lock member 500 is positioned at the lock position.

The eject member 400 can eject the drive bay 100 in the eject direction when the lock member 500 is positioned at the unlock position. With reference to FIG. 2, the press portion 410, the pressed portion 112, the receive portion 510 and the received portion 114 are arranged at an imaginary straight line when the lock member 500 is positioned at the lock position. The imaginary straight line extends in the X-direction.

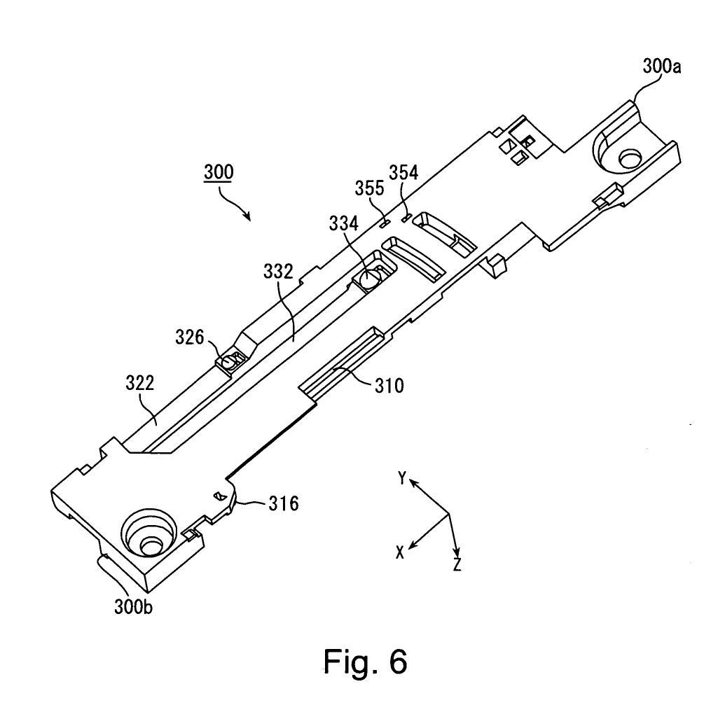

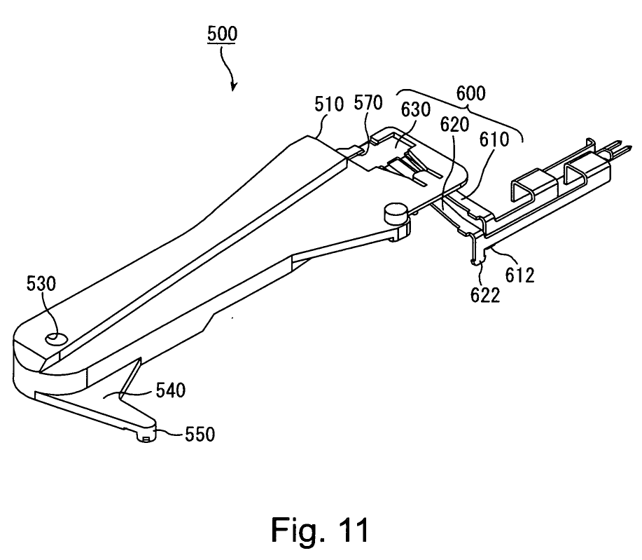

With reference to FIG. 11, the detector 600 is configured to detect whether the lock member 500 is positioned at the lock position or the unlock position. The detector 600 comprises a first conductor 610, a second conductor 620 and a connect portion 630. The first conductor 610 has an L-like shape and has a press fit portion 612. The second conductor 620 has an L-like shape and has a press fit portion 622. The press fit portions 612 and 622 project downwardly in the Z-direction, respectively. The first conductor 610 and the second conductor 620 are held by the hold portions 351 and 352, respectively, of the base member 300 (See FIG. 5). The first conductor 610 and the second conductor 620 are partially accommodated by the accommodation portion 353 of the base member 300. The press fit portions 612 and 622 are inserted into the press fitted portions 354 and 355, respectively (See FIG. 6). The first conductor 610 is not electrically connected to the second conductor 620 when the first conductor 610 and the second conductor 620 are held by the base member 300. The connect portion 630 is held by the hold portion 570 of the lock member 500. The connect portion 630 is configured to electrically connect the first conductor 610 and the second conductor 620 when the lock member 500 is positioned at the unlock position. Therefore, the detector 600 can detect whether the lock member 500 is positioned at the lock position or the unlock position.

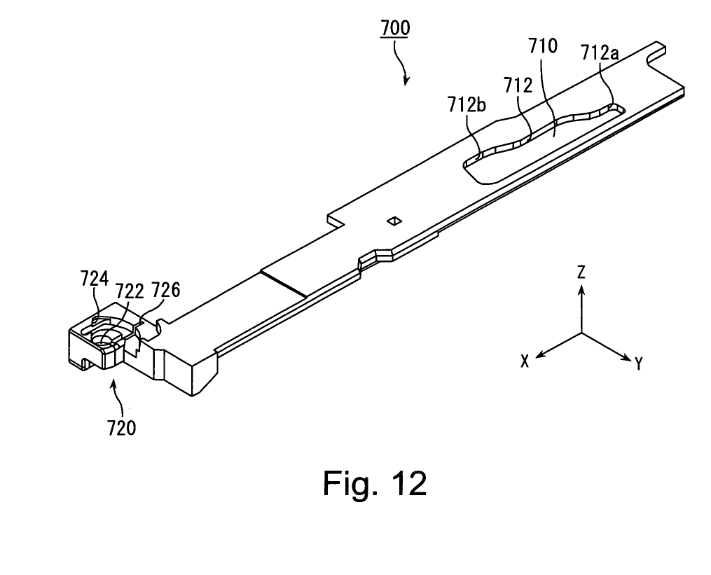

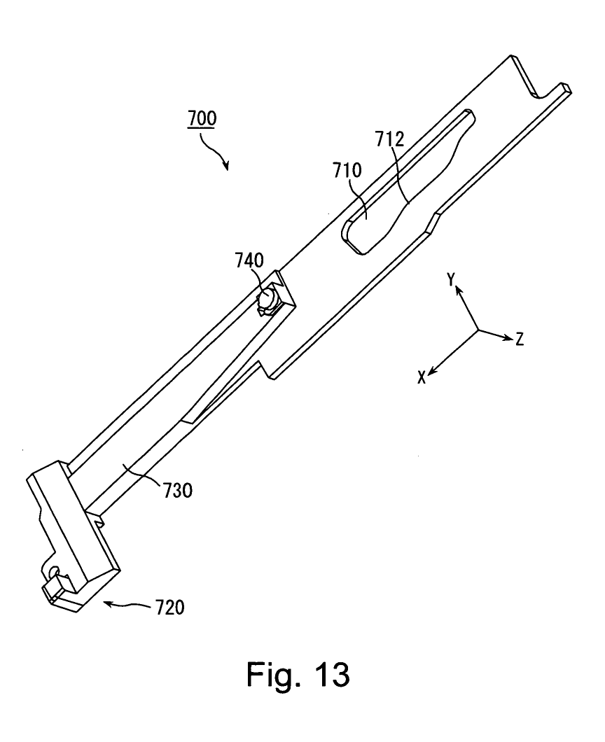

With reference to FIGS. 12 and 13, the lock release member 700 is configured to release the lock of the drive bay 100 by the lock member 500. The lock release member 700 comprises a cam hole 710, a lever hold portion 720, a guided portion 730 and a projection 740. The cam hole 710 has a cam surface 712. The lever hold portion 720 is configured to hold the lever 800. The lock release member 700 has a top side and a bottom side in the Z-direction. The guided portion 730 is formed on the bottom side. The projection 740 is formed on the guided portion 730.

With reference to FIGS. 2 and 3, the lock release member 700 is supported by the base member 300 so that the cam follower 520 of the lock member 500 is positioned in the cam hole 710. The guided portion 730 of the lock release member 700 is guided by the guide portion 331 of the base member 300. As showing in FIG. 4, the projection 740 is arranged within the opening 332 of the base member 300. With this structure, the lock release member 700 is movable in the X-direction.

With reference to FIG. 4, the eject mechanism 200 is provided with a coil spring 750 which connects the projection 740 of the lock release member 700 and the projection 334 of the base member 300. Therefore, the coil spring 750 serves as a lock release bias member which biases the lock release member 700 in the insert direction.

With reference to FIGS. 2, 12 and 13, the cam surface 712 has a front part 712a and a back part 712b in the X-direction. The cam surface 712 is sloped in the Y-direction so that the front part 712a of the cam surface 712 is farther from the drive bay 100 than the back part 712b of the cam surface 712 in the Y-direction. The cam follower 520 of the lock member 500 is brought into contact with the cam surface 712 in accordance with the bias by the coil spring 560. With this structure, the cam follower 520 follows the cam surface 712 between the back part 712b and the front part 712a. In other words, the cam follower 520 is moved in the Y-direction when the lock release member 700 is substantially moved in the eject direction. With this structure, the lock member 500 is moved from lock position to unlock position in the Y-direction when the lock release member 700 is moved in the eject direction.

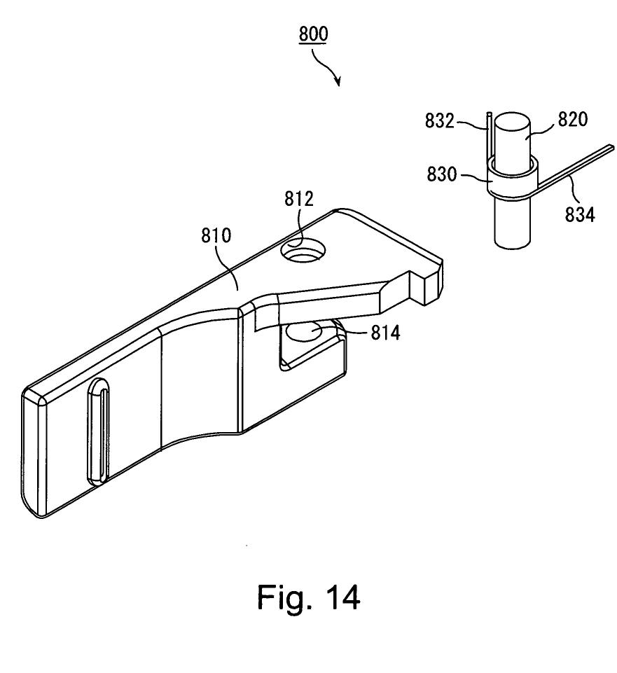

With reference to FIGS. 2, 3 and 14, the lever 800 is used to move the lock release member 700 in the eject direction when the lever 800 is pulled in the eject direction. The lever 800 comprises a tab 810, a shaft 820 and a torsion coil spring 830. The lever 800 is pivotable between a set position and a pull position. The lever 800 is directed to the Y-direction when the lever 800 is positioned at the set position. The lever 800 is directed to the eject direction when the lever 800 is positioned at the pull position. The lever 800 is held by the lever hold portion 720 of the lock release member 700 (See FIG. 12). The lever hold portion 720 comprises a shaft hole 722, a contact portion 724 and a hold portion 726. The torsion coil spring 830 has two end portions 832 and 834. In this embodiment, the torsion coil spring 830 is held by the lever hold portion 720 so that the end portion 832 is brought into contact with the contact portion 724 of the lever hold portion 720 while the end portion 834 is held by the hold portion 726 of the lever hold portion 720. The tab 810 has two shaft holes 812 and 814. The tab 810 is attached on the lever hold portion 720 so that the shaft holes 812 and 814 are aligned with the shaft hole 722 of the lever hold portion 720 in the Z-direction. The shaft 820 is inserted into the shaft holes 812, 722 and 814. Therefore, the torsion coil spring 830 served as a lever bias member which the biases lever 800 so that the lever 800 is positioned at the set position.

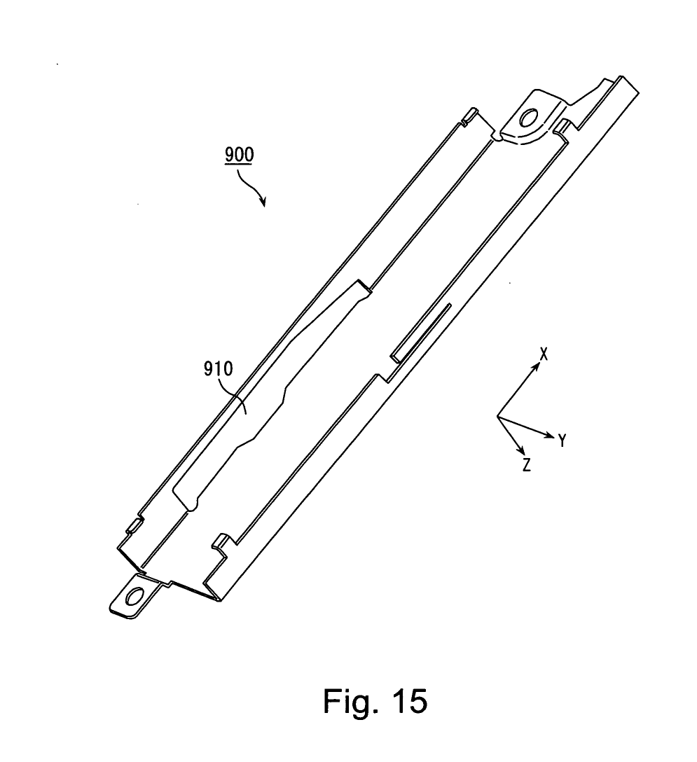

With reference to FIGS. 1 and 15, the cover 900 covers the base member 300, the eject member 400, the lock member 500, the detector 600 and the lock release member 700. The cover 900 comprises a window 910. The press portion 410 of the eject member 400 and the receive portion 510 of the lock member 500 projects out of the cover 900 through the window 910.

With the structure as described above, the eject mechanism 200 of the embodiment is operated as follows. With reference to FIG. 2, when the lever 800 is pulled and moved in the eject direction, the lock release member 700 is moved in the eject direction. The cam follower 520 is moved along the cam surface 712 from the back part 712b to the front part 712a in accordance with the movement of the lock release member 700. As the result, the lock member 500 is moved from the lock position to the unlock position. The drive bay 100 is ejected, i.e. is moved from predetermined position by the eject member 400 in the eject direction.

The eject mechanism 200 of the present embodiment can eject the drive bay 100 only when the lever 800 is pulled in the eject direction so that the lock release member 700 is moved in the eject direction. Therefore, the drive bay 100 is not ejected even if the drive bay 100 or the lock release member 700 is pushed in the insert direction unexpectedly.

### Second Embodiment

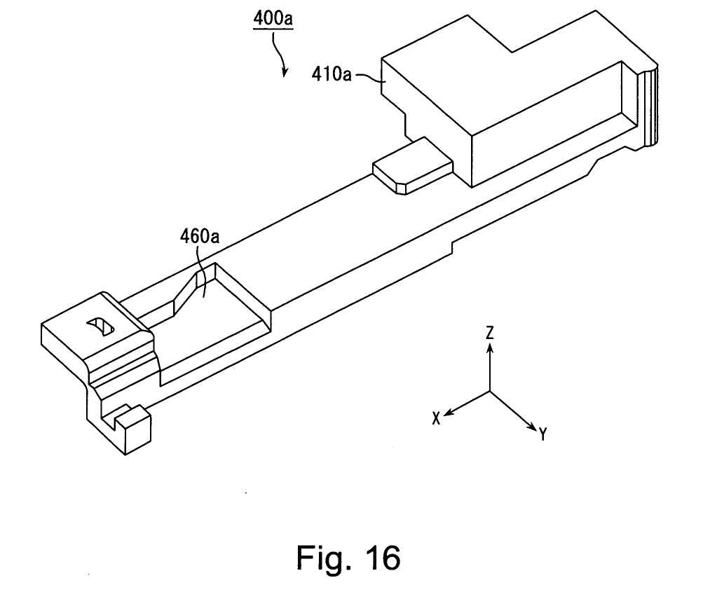

An eject mechanism 200 according to a second embodiment is similar to that of the first embodiment. In FIGS. 16 to 19, the same reference numbers are given to the components same as those illustrated in FIGS. 1 to 15, and the description therefor will be omitted. In the first embodiment, the drive bay 100 comprises the received portion 114 received by the receive portion 510 of the lock member 500. With reference to FIG. 16, the eject member 400 of the second embodiment comprises a received portion 460a. The received portion 460a has a recess shape.

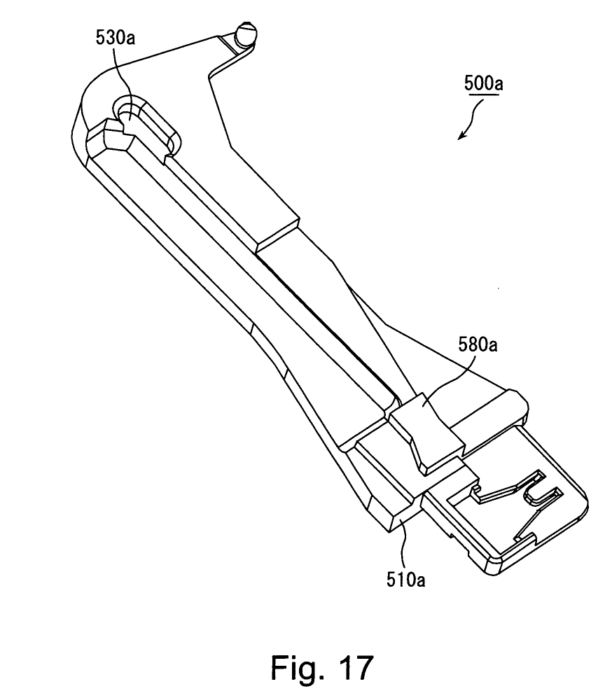

With reference to FIG. 17, the lock member 500a of the present embodiment comprises a receive portion 580a. The receive portion 580a has a projection shape. The receive portion 580a projects downward in the Z-direction. The receive portion 580a and the received portion 460a are positioned farther from the drive bay 100 in the Y-direction than the press portion 410a and the pressed portion 112.

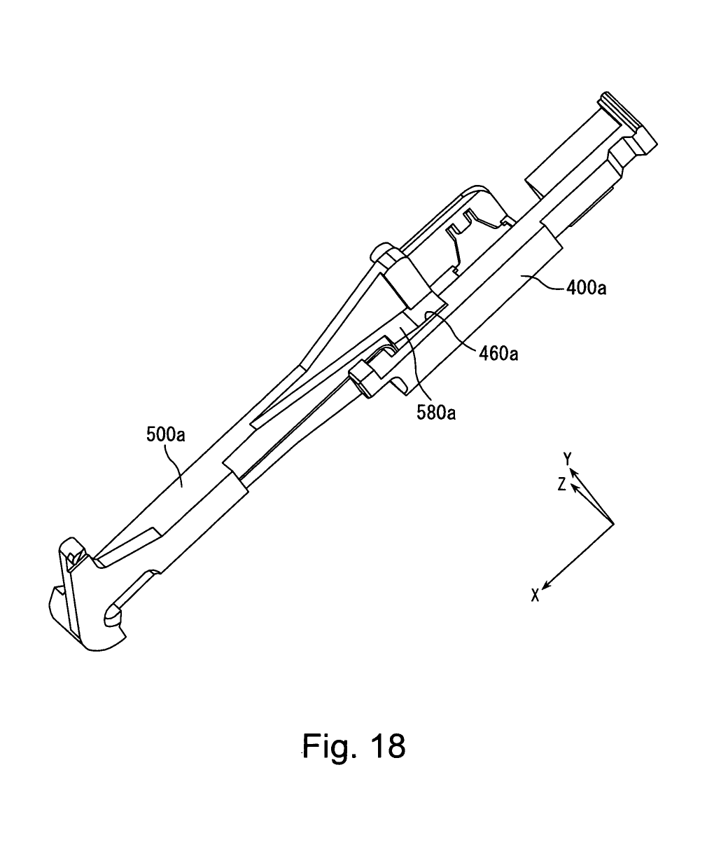

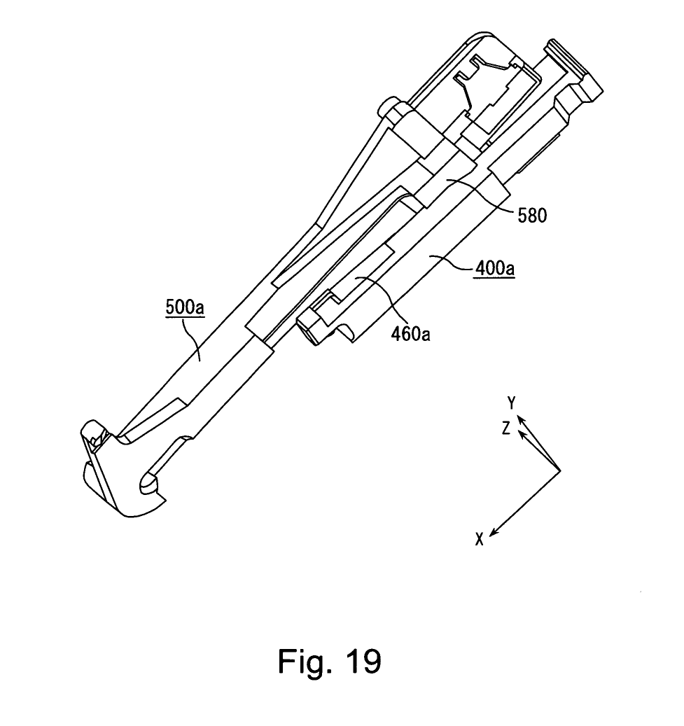

With reference to FIGS. 18 and 19, the received portion 460a is received by the receive portion 580a when the lock member 500a is positioned at the lock position so that the lock member 500 locks the eject member 400a. On the other hand, the received portion 460a is not received by the receive portion 580a when the lock member 500a is positioned at the unlock position so that the drive bay 100 is ejected in the eject direction by the eject member 400a. In this embodiment, the receive portion 510a (shown in FIG. 17) is not receive the received portion 114 of the drive bay 100.

The drive bay 100 of the second embodiment is also ejected only when the lock release member 700 is moved in the eject direction. Therefore, the drive bay 100 is not ejected even if the drive bay 100 or the lock release member 700 is pushed in the insert direction unexpectedly.

As described above, the eject mechanism 200 of the present embodiment ejects the drive bay 100 only when the lock release member 700 is moved in the eject direction. The movement of the lock release member 700 occurs only upon the intentional operation of the lever 800 by the operation. Therefore, an irregular ejection of the drive bay 100 can be prevented.

The present application is based on a Japanese patent application of JP 2008-202028 filed before the Japan Patent Office on Aug. 5, 2008, the contents of which are incorporated herein by reference.

While there has been described what is believed to be the preferred embodiment of the invention, those skilled in the art will recognize that other and further modifications may be made thereto without departing from the spirit of the invention, and it is intended to claim all such embodiments that fall within the true scope of the invention.

What is claimed is:

1. An eject mechanism comprising:
an eject member configured to, when an object is positioned at a predetermined position, eject the object from the predetermined position along an eject direction;
a lock member configured to lock the object on the predetermined position against the eject member; and
a lock release member configured to, when the lock release member is moved in the eject direction, release the lock of the object by the lock member.

2. The eject mechanism according to claim 1, the object comprising a pressed portion, wherein the eject mechanism further comprises an eject bias member which biases the eject member in the eject direction, the eject member comprising a press portion which presses the pressed portion of the object in the eject direction in accordance with the bias by the eject bias member.

3. The eject mechanism according to claim 1, wherein the lock member is movable between a lock position and an unlock position, the lock member being lockable the object when the lock member is positioned at the lock position, the lock release member being configured to move the lock member from the lock position to the unlock position when the lock release member is moved in the eject direction so that the object is ejected.

4. The eject mechanism according to claim 3, the object comprising a received portion, wherein the lock member further comprises a receive portion, the receive portion being configured to receive the received portion in the eject direction when the lock member is positioned at the lock position so that the lock member locks the object on the predetermined position.

5. The eject mechanism according to claim 4, the object comprising a projection projecting in a direction perpendicular to the eject direction, the projection comprising the pressed portion and the received portion, wherein the press portion, the pressed portion, the received portion and the receive portion are arranged on an imaginary straight line when the lock member is positioned at the lock position, the imaginary straight line extending in the eject direction.

6. The eject mechanism according to claim 3, wherein the eject member comprises a received portion, the lock member further comprising a receive portion, the receive portion being configured to receive the received portion when the lock member is positioned at the lock position so that the lock member locks the object on the predetermined position.

7. The eject mechanism according to claim 6, wherein the receive portion and the received portion are positioned farther from the object than the press portion and the pressed portion in a direction perpendicular to the eject direction.

8. The eject mechanism according to claim 3, wherein the lock member is movable between the lock position and the unlock position in a direction perpendicular to the eject direction.

9. The eject mechanism according to claim 3, further comprising a lock bias member which biases the lock member so that the lock member is positioned at the lock position.

10. The eject mechanism according to claim 9, wherein the lock release member comprises a cam surface, the lock member comprising a cam follower which is brought into contact with the cam surface by the lock bias member, the cam follower following the cam surface when the lock release member is moved in the eject direction, so that the lock member is shifted from the lock position to the unlock position.

11. The eject mechanism according to claim 10, further comprising a lock release bias member which biases the lock release member in an insert direction opposite to the eject direction.

12. The eject mechanism according to claim 1, further comprising a lever, the lever being attached to the lock release member so that the lock release member is moved in the eject direction when the lever is pulled in the eject direction.

13. The eject mechanism according to claim 12, further comprising a lever bias member, wherein the lock release member supports the lever so that the lever is pivotable between a set position and a pull position, the lever being directed to a direction perpendicular to the eject direction when the lever is positioned at the set position, the lever being directed to the eject direction when the lever is positioned at the pull position, the lever bias member biasing the lever so that the lever is positioned at the set position.

14. The eject mechanism according to claim 3, further comprising a detector configured to detect whether the lock member is positioned at the lock position or the unlock position.

15. The eject mechanism according to claim 14, wherein the detector comprises a first conductor, a second conductor and a connect portion, the connect portion being attached to the lock member, the connect portion electrically connecting between the first conductor and the second conductor when the lock member is positioned at the unlock position.

16. An electrical apparatus comprising the eject mechanism according to claim 1.
